(19) United States
(12) Patent Application Publication
(10) Pub. No.: US 2024/0195359 A1
(43) Pub. Date: Jun. 13, 2024

(54) PIEZOELECTRIC OSCILLATOR

(71) Applicant: Murata Manufacturing Co., Ltd., Nagaokakyo-shi (JP)

(72) Inventor: Yuuki OOI, Nagaokakyo-shi (JP)

(21) Appl. No.: 18/586,004

(22) Filed: Feb. 23, 2024

Related U.S. Application Data
(63) Continuation of application No. PCT/JP22/17502, filed on Apr. 11, 2022.

(30) Foreign Application Priority Data
Sep. 6, 2021 (JP) 2021-144872

(51) Int. Cl. H03B 5/32; H03H 9/19

(52) U.S. Cl. CPC H03B 5/32; H03H 9/19; H03B 2200/0018

(57) ABSTRACT

A piezoelectric oscillator includes: a piezoelectric vibrating element having a piezoelectric strip, a first excitation electrode, and a second excitation electrode; a first crystal substrate bonded to the piezoelectric strip; and a second crystal substrate bonded to the piezoelectric strip. The first crystal substrate has a principal surface defined by a first basic axis and a second basic axis that intersects the first basic axis, and when an axis obtained by inclining, among mutually intersecting first, second, and third crystallographic axes of a material of the first crystal substrate, the third axis around the first axis by a first predetermined angle is regarded as a first inclined axis, the first axis corresponds to the first basic axis and the first inclined axis corresponds to the second basic axis, the first predetermined angle is any angle included in an angle range of −90 to −60 degrees and 80 to 90 degrees.

### CROSS REFERENCE TO RELATED APPLICATIONS

The present application is a continuation of International application No. PCT/JP2022/017502, filed Apr. 11, 2022, which claims priority to Japanese Patent Application No. 2021-144872, filed Sep. 6, 2021 the entire contents of each of which are incorporated herein by reference.

### TECHNICAL FIELD

The present invention relates to a piezoelectric oscillator.

### BACKGROUND ART

Conventionally, a piezoelectric oscillator with a thickness-sliding vibration as the main vibration is widely used as a signal source for reference signals used in an oscillation device, a band filter and the like. For example, Japanese Patent No. 5492697 (“Patent Document 1”) discloses a configuration in which a crystal lid wafer (first crystal substrate) bonded to a first surface of an AT-cut crystal wafer (piezoelectric vibrating element) and a crystal base wafer (second crystal substrate) bonded to a second surface of the AT-cut crystal wafer are each cut within a range of 24° 00′ to 32° 28′ from a Z axis, which is a crystallographic axis of crystal. With such a configuration, the stress transmitted from the crystal base wafer and crystal lid wafer to the AT-cut crystal wafer is reduced by reducing the difference in thermal expansion coefficient between the crystal lid wafer and crystal base wafer and the AT-cut crystal wafer.

### SUMMARY OF THE INVENTION

However, in the conventional technology, for example, when the piezoelectric oscillator is mounted on a mounting board, an external stress caused by the difference in thermal expansion coefficient between the mounting board and a piezoelectric strip of the piezoelectric vibrating element may be transmitted to the piezoelectric oscillator.

The present invention has been made in view of such circumstances, and it is an object of the present invention to provide a piezoelectric oscillator capable of reducing the stress transmitted to the piezoelectric vibrating element.

A piezoelectric oscillator according to an aspect of the present invention includes: a piezoelectric vibrating element that includes a piezoelectric strip, a first excitation electrode on a first surface of the piezoelectric strip, and a second excitation electrode on a second surface of the piezoelectric strip; a first crystal substrate having an external terminal and bonded to the first surface of the piezoelectric strip; and a second crystal substrate bonded to the second surface of the piezoelectric strip. The first crystal substrate has a principal surface defined by a first basic axis and a second basic axis that intersects the first basic axis, and when an axis obtained by inclining, among mutually intersecting first axis, second axis, and third axis, which are crystallographic axes of crystal, the third axis around the first axis by a first predetermined angle is regarded as a first inclined axis, the first axis corresponds to the first basic axis and the first inclined axis corresponds to the second basic axis, the first predetermined angle is any angle included in an angle range of −90 to −60 degrees and 80 to 90 degrees.

According to the present invention, the stress transmitted to the piezoelectric vibrating element can be reduced.

### BRIEF DESCRIPTION OF THE DRAWINGS

FIG. 1 is a cross-sectional view schematically showing a configuration of a crystal oscillator according to one embodiment.

FIG. 2 is a plan view schematically showing a configuration of a device substrate according to one embodiment.

FIG. 3 a cross-sectional view taken along the arrows III-III of FIG. 2.

FIG. 4 is a table showing an example of the characteristics of a crystal unit for each combination of the cut angle of a CAP substrate and the cut angle of a handle substrate.

FIG. 5 is a graph showing the characteristics of the crystal unit for each combination of the cut angle of the CAP substrate and the cut angle of the handle substrate.

FIG. 6 is a graph showing the characteristics of the crystal unit for each combination of the cut angle of the CAP substrate and the cut angle of the handle substrate.

FIG. 7 is a view showing the characteristics of the crystal unit under each condition.

FIG. 8 is a table showing the characteristics of the crystal unit under each condition.

FIG. 9 is a cross-sectional view schematically showing a configuration of a crystal unit according to another embodiment.

FIG. 10 is a cross-sectional view schematically showing a configuration of a crystal unit according to another embodiment.

### DETAILED DESCRIPTION OF THE PREFERRED EMBODIMENTS

One embodiment of a piezoelectric oscillator of the present disclosure embodied in a crystal unit is described below.

For convenience, each drawing may be accompanied by a Cartesian coordinate system consisting of X axis, Y′ axis and Z′ axis to clarify the relationship between the drawings and to help understand the positional relationship of each component. The X axis, Y′ axis and Z′ axis correspond to each other in each drawing. The X axis, Y′ axis and Z′ axis correspond to the crystallographic axes of crystal, respectively. The X axis corresponds to the electrical axis (polarity axis), the Y axis to the mechanical axis, and the Z axis to the optical axis. The Y′ axis and the Z′ axis are axes obtained by rotating the Y axis and the Z axis by 35 degrees 15 minutes±1 minute 30 seconds from the Y axis to the Z axis around the X axis, respectively. The X axis is an example of a first axis, the Y axis is an example of a second axis, and the Z axis is an example of a third axis.

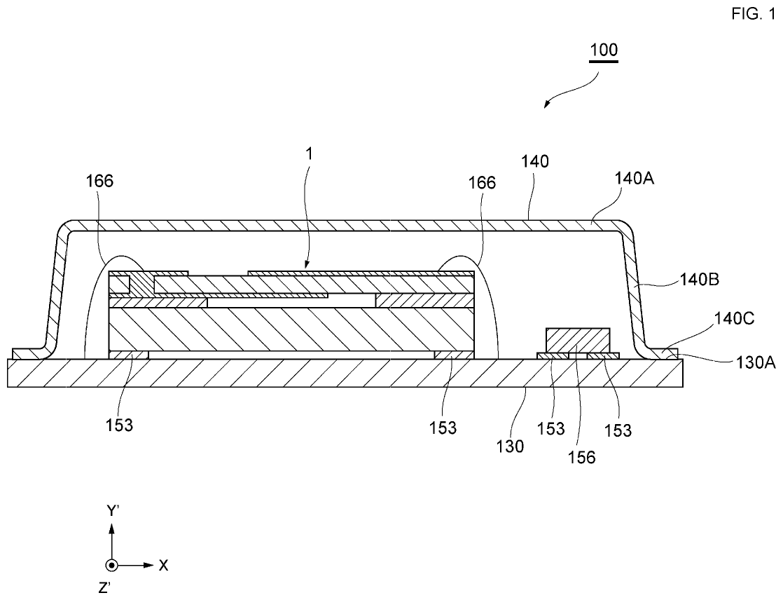

As shown in FIG. 1, a crystal oscillator 100 includes, for example, a crystal unit 1, a mounting board 130, a lid member 140, and electronic components 156.

The crystal unit 1 and the electronic components 156 are housed in a space between the mounting board 130 and the lid member 140. The crystal unit 1 is electrically connected to a wiring layer of the mounting board 130 by, for example, a bonding wire 166. The crystal unit 1 is electrically connected to the wiring layer of the mounting board 130 by, for example, a solder 153. The space between the mounting board 130 and the lid member 140 is hermetically sealed. The space between the mounting board 130 and the lid member 140 may be, for example, in a vacuum state or in a state filled with a gas such as an inert gas.

The mounting board 130 is a flat circuit board and includes, for example, a glass epoxy board and a wiring layer patterned on the glass epoxy board. The mounting board 130 may include, for example, an alumina substrate and a wiring layer patterned on the alumina substrate.

The lid member 140 is made of, for example, a metal material and includes a top portion 140A, a side wall portion 140B, and a flange portion 140C. The side wall portion 140B extends from an outer edge of the top portion 140A toward the mounting board 130. The flange portion 140C protrudes outward from a tip of the side wall portion 140B and is bonded to a first surface 130A of the mounting board 130.

The electronic components 156 are composed of, for example, capacitors, IC chips and the like, and are bonded to the first surface 130A of the mounting board 130. The electronic components 156 are bonded to the wiring layer of the mounting board 130 by, for example, the solder 153. The electronic components 156 include, for example, an oscillation circuit, which is a circuit that oscillates the crystal unit 1, and a part of a temperature compensation circuit, which is a circuit that compensates for the temperature characteristics of the crystal unit 1.

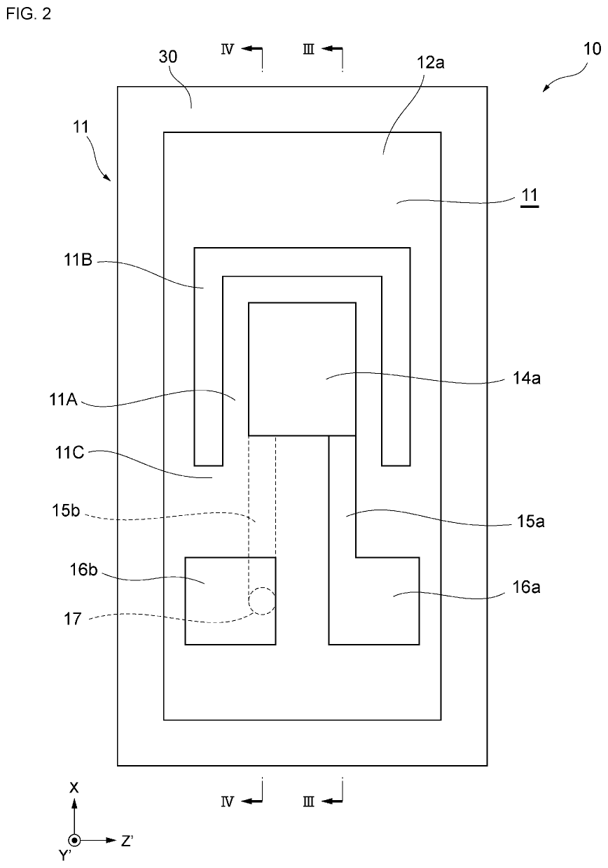

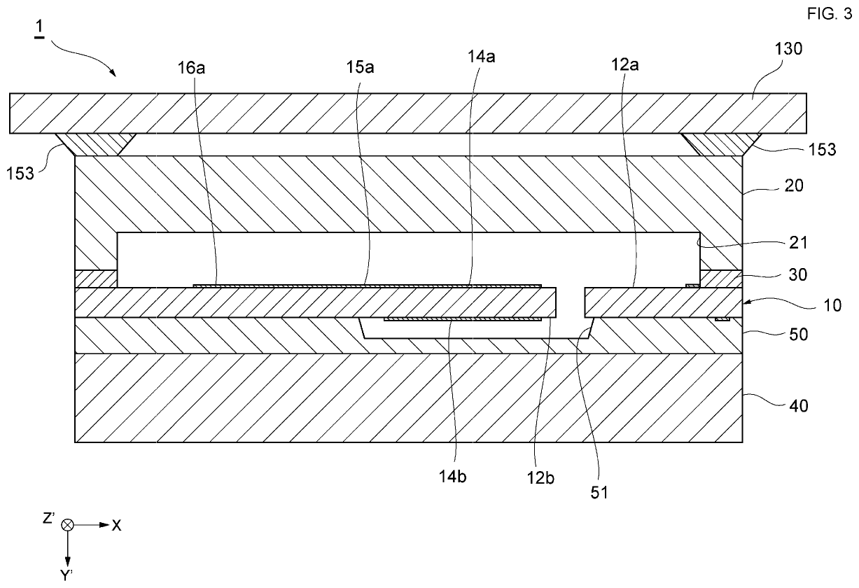

As shown in FIGS. 2 and 3, the crystal unit 1 includes, for example, a device substrate 10, a CAP substrate 20, a bonding portion 30, a handle substrate 40, and a bonding layer 50. The device substrate 10 is an example of a piezoelectric vibrating element. The CAP substrate 20 is an example of a first crystal substrate. The handle substrate 40 is an example of a second crystal substrate.

The device substrate 10 includes a crystal strip 11, a first excitation electrode 14a provided on a first principal surface 12a of the crystal strip 11, and a second excitation electrode 14b provided on a second principal surface 12b of the crystal strip 11. The crystal strip 11 is formed by etching a crystal substrate (for example, a crystal wafer), which is obtained by cutting and polishing a crystalline body of a synthetic quartz crystal. The first excitation electrode 14a and the second excitation electrode 14b are provided to face each other with the crystal strip 11 interposed therebetween. The first excitation electrode 14a and the second excitation electrode 14b are rectangular in shape when viewed in plan view of the first principal surface 12a of the crystal strip 11, and are arranged so as to overlap each other in their entirety. The shape of the first excitation electrode 14a and the second excitation electrode 14b in plan view is not limited to a rectangular shape, but may be a polygonal shape, a circular shape, an oval shape, or a combination of these shapes.

The crystal strip 11 is, for example, an AT-cut type crystal substrate, and includes a vibrating portion 11A, a groove 11B, a holding portion 11C, extended electrodes 15a and 15b, connecting electrodes 16a and 16b, and a via electrode 17.

The vibrating portion 11A has a rectangular shape in plan view of the first principal surface 12a of the crystal strip 11, and vibrates at a predetermined oscillation frequency with a thickness-shear vibration as the main vibration.

The groove 11B is formed so as to surround the vibrating portion 11A in plan view of the first principal surface 12a of the crystal strip 11, and passes through the crystal strip 11 in the thickness direction.

The holding portion 11C is connected to an end portion of the vibrating portion 11A in the X-axis direction and holds the vibrating portion 11A.

The extended electrode 15a is provided on the first principal surface 12a of the crystal strip 11 and electrically connects the first excitation electrode 14a and the connecting electrode 16a. The extended electrode 15b is provided on the second principal surface 12b of the crystal strip 11 and electrically connects the second excitation electrode 14b and the connecting electrode 16b. The via electrode 17 passes through the crystal strip 11 in the thickness direction. The via electrode 17 electrically connects the extended electrode 15b and the connecting electrode 16b.

The crystal strip 11 applies an alternating electric field to the first excitation electrode 14a and the second excitation electrode 14b via the extended electrodes 15a and 15b, the connecting electrodes 16a and 16b, and the via electrode 17, thereby causing the vibrating portion 11A to vibrate in a predetermined vibration mode.

The CAP substrate 20 is composed of, for example, a crystal substrate. The CAP substrate 20 has an external terminal, and when the CAP substrate 20 is mounted on the mounting board 130, the external terminal of the CAP substrate 20 is electrically connected to the wiring layer of the mounting board 130. The CAP substrate 20 has a recess 21 formed, for example, in a portion corresponding to the vibrating portion 11A of the device substrate 10. The space formed by the device substrate 10 and the recess 21 of the CAP substrate 20 forms a part of the vibration space of the vibrating portion 11A. The lower end of the CAP substrate 20 is bonded to the first principal surface 12a of the crystal strip 11. The lower end of the CAP substrate 20 is, for example, bonded to the first principal surface 12a of the crystal strip 11 via the bonding portion 30. The lower end of the CAP substrate 20 may also be, for example, directly bonded to the first principal surface 12a of the crystal strip 11 without the bonding portion 30.

When an axis obtained by inclining, among the mutually intersecting X axis, Y axis, and Z axis, which are the crystallographic axes of crystal, the Z axis around the X axis by a first predetermined angle is regarded as a Z′ axis (third inclined axis), the CAP substrate 20 causes the X axis to correspond to a first basic axis and causes the Z′ axis to correspond to a second basic axis. In such a case, in the CAP substrate 20, for example, a surface parallel to a plane defined by the Z′ axis obtained by inclining the Z axis around the X axis by the first predetermined angle and the X axis becomes the principal surface. The first predetermined angle corresponds to the cut angle of the CAP substrate 20.

The bonding portion 30 is provided between the CAP substrate 20 and the first principal surface 12a of the crystal strip 11, over the entire periphery of each of the CAP substrate 20 and the device substrate 10. The bonding portion 30 has electric insulation (electric non-conductivity). The bonding portion 30 contains, for example, Au as a main component. The main component of the bonding portion 30 may be SiO₂ or a resin material. The CAP substrate 20 may be directly bonded to the device substrate 10, mitting the bonding portion 30. When the main component of the bonding portion 30 is Au, for example, Au thin films formed on the CAP substrate 20 and the device substrate 10 are activated by plasma or other means, and the surfaces of both are bonded to each other by applying a load. When the main component of the bonding portion 30 is SiO₂, for example, a silicon oxide film is formed on the CAP substrate 20 and the device substrate 10 by vapor deposition or sputtering, and the surfaces of both are cleaned and bonded to each other in a vacuum. When the main component of the bonding portion 30 is a resin material, the resin material may include a thermosetting resin or a light-curing resin; for example, an epoxy resin may be used. When directly bonding the CAP substrate 20 and the device substrate 10, for example, the principal surface of the CAP substrate 20 and the principal surface of the device substrate 10 are mirror-polished to make them hydrophilic, the both principal surfaces are brought into contact with each other and heat-treated to remove H₂O from the both principal surfaces, thereby bonding the CAP substrate 20 and the device substrate 10 by siloxane bonding.

The handle substrate 40 is composed of, for example, a crystal substrate. The handle substrate 40 is formed into, for example, a flat plate shape and supports the device substrate 10 so that the device substrate 10 can vibrate.

When an axis obtained by inclining, among the mutually intersecting X axis, Y axis, and Z axis, which are the crystallographic axes of crystal, the Z axis around the X axis by a second predetermined angle is regarded as a Z′ axis (third inclined axis), the handle substrate 40 causes the X axis to correspond to a third basic axis and causes the Z′ axis to correspond to a fourth basic axis. In the handle substrate 40, for example, a surface parallel to a plane defined by the Z′ axis obtained by inclining the Z axis around the X by the second predetermined angle and the X axis becomes the principal surface. The second predetermined angle corresponds to the cut angle of the handle substrate 40.

The bonding layer 50 bonds the device substrate 10 to the handle substrate 40. The bonding layer 50, for example, is provided on the upper surface of the handle substrate 40 and bonds the upper surface of the handle substrate 40 to the second principal surface 12b of the crystal strip 11. The bonding layer 50 bonds the device substrate 10 to the handle substrate 40, thereby enabling the device substrate 10 to be sealed between the CAP substrate 20 and the handle substrate 40, for example. The bonding layer 50 has a recess 51 formed in a portion corresponding to the vibrating portion 11A of the device substrate 10. The space formed by the device substrate 10 and the recess 51 of the bonding layer 50 forms a part of the vibration space of the vibrating portion 11A.

The bonding layer 50 is composed of, for example, a silicon oxide film and bonds the upper surface of the handle substrate 40 to the second principal surface 12b of the crystal strip 11. The bonding layer 50 contains, for example, Au as a main component. The main component of the bonding layer 50 may also be SiO₂ or a resin material. The resin material may include a thermosetting resin or a light-curing resin; for example, an epoxy resin may be used. The handle substrate 40 may be directly bonded to the device substrate 10, omitting the bonding layer 50. When the main component of the bonding layer 50 is Au, for example, Au thin films formed on the handle substrate 40 and the device substrate 10 are activated by plasma or other means, and the surfaces of both are bonded to each other by applying a load. When the main component of the bonding layer 50 is SiO₂, for example, a silicon oxide film is formed on the handle substrate 40 and the device substrate 10 by vapor deposition or sputtering, and the surfaces of both are cleaned and bonded to each other in a vacuum. When the main component of the bonding layer 50 is a resin material, the resin material may include a thermosetting resin or a light-curing resin; for example, an epoxy resin may be used. When directly bonding the handle substrate 40 and the device substrate 10, for example, the principal surface of the handle substrate 40 and the principal surface of the device substrate 10 are mirror-polished to make them hydrophilic, the both principal surfaces are brought into contact with each other and heat-treated to remove H₂O from the both principal surfaces, thereby bonding the handle substrate 40 and the device substrate 10 by siloxane bonding.

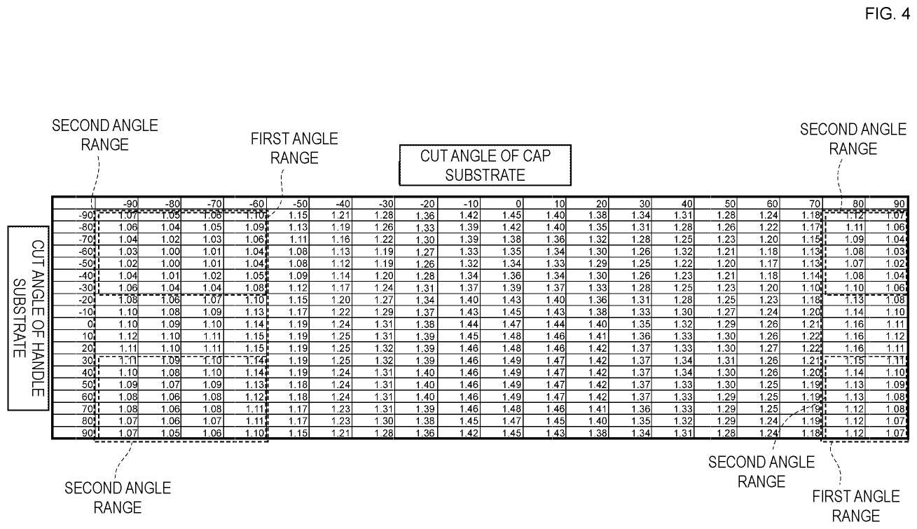

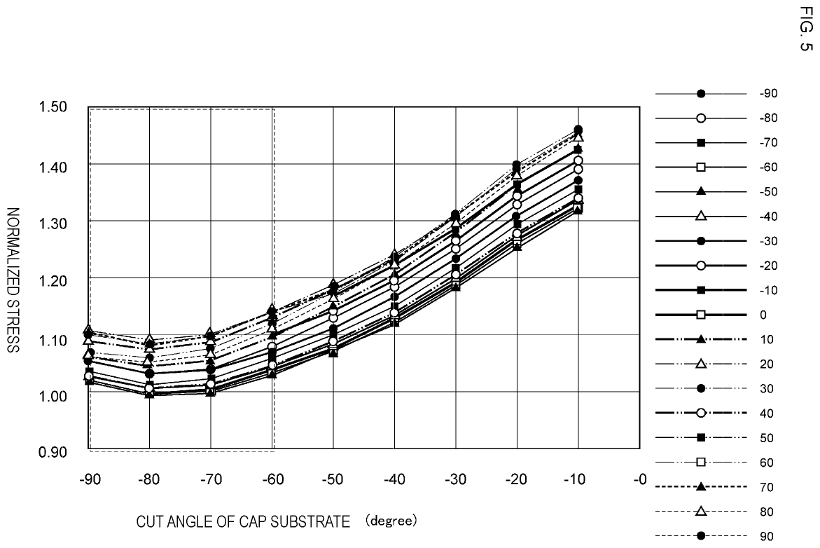

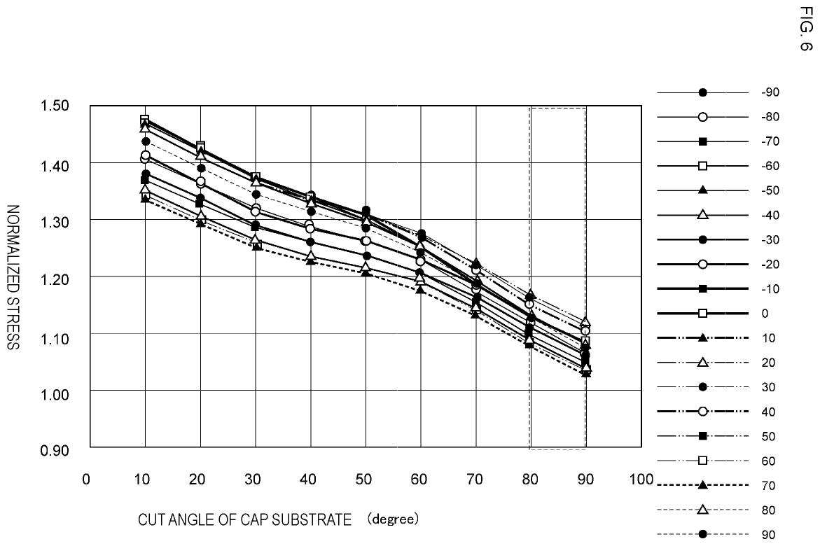

Next, the configuration of the crystal unit 1 according to the present embodiment is described with reference to FIGS. 4 to 8. FIGS. 4 to 6 show the characteristics of the crystal unit 1 predicted using a simulation model of the crystal unit 1 according to the present embodiment. In the simulation model, the thickness of the CAP substrate 20 is 150 μm, the thickness of the bonding portion 30 is 100 nm, the thickness of the device substrate 10 is 1 μm, the thickness of the bonding layer 50 is 1 μm, and the thickness of the handle substrate 40 is 150 μm. FIGS. 4 to 6 show the magnitude of the stress applied to the device substrate 10 during vibration of the crystal unit 1 for each combination of the cut angle of the CAP substrate 20 and the cut angle of the handle substrate 40. In the examples shown in FIGS. 4 to 6, the magnitude of the stress applied to the device substrate 10 is indicated as a normalized value, and the smaller of the value is, the better the characteristics of the crystal unit 1 are. In such an example, as indicated by the wavy lines in FIGS. 5 and 6, the stress applied to the device substrate 10 is relatively small when: an angle range of −90 to −60 degrees and an angle range of 80 to 90 degrees correspond to a first angle range, and the cut angle of the CAP substrate 20 is any angle included in the first angle range. In other words, it is preferred that the cut angle of the CAP substrate 20 is any angle in the angle range of −90 to −60 degrees and the angle range of 80 to 90 degrees. Further, in such an example, the stress applied to the device substrate 10 is smaller when: angle ranges of −90 to −30 degrees and 30 to 90 degrees correspond to a second angle range, and the cut angle of the CAP substrate 20 is any angle in the first angle range and the cut angle of the handle substrate 40 is any angle in the second angle range. In other words, it is preferred that the cut angle of the handle substrate 40 is any angle in the angle range of −90 to −30 degrees and the angle range of 30 to 90 degrees when the cut angle of the CAP substrate 20 is any angle in the angle range of −90 to −60 degrees and the angle range of 80 to 90 degrees.

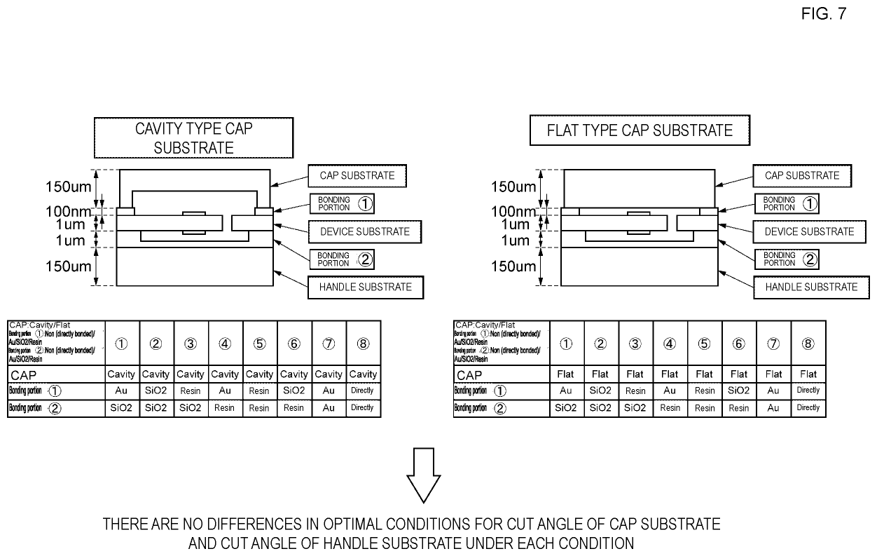

FIG. 7 illustrates the characteristics of the crystal unit 1 according to the present embodiment for each condition. The example shown in FIG. 7 shows the characteristics of the crystal unit 1 under each condition when the material of the bonding portion 30 and the material of the bonding layer 50 are changed for the case where the recess 21 is formed in the CAP substrate 20 and the case where the recess 21 is not formed in the CAP substrate 20, respectively. Specifically, the example shown in FIG. 7 shows the characteristics of the crystal unit 1 for each condition when the main component of the material of the bonding portion 30 and the main component of the material of the bonding layer 50 are each Au, SiO₂, or resin, or when the CAP substrate 20 and the handle substrate 40 are directly bonded to the device substrate 10, omitting the bonding portion 30 and the bonding layer 50. In such an example, in a similar manner to the cases shown in FIGS. 4 to 6, based on the characteristics of the crystal unit 1 predicted using a simulation model of the crystal unit 1 for each condition, it is known that there are no differences in the optimal conditions for the cut angle of the CAP substrate 20 and the cut angle of the handle substrate 40 under each condition.

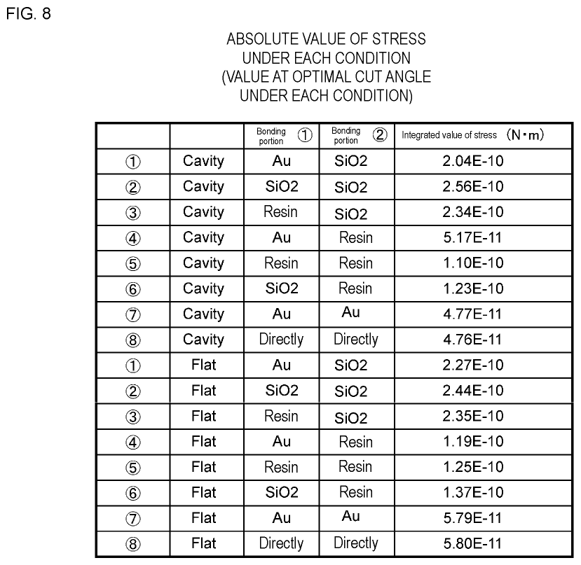

FIG. 8 shows the characteristics of the crystal unit 1 according to the present embodiment for each condition. In the example shown in FIG. 8, under each condition set as in the case shown in FIG. 7, the magnitude of the stress applied to the device substrate 10 is shown as an absolute value before normalization. In the example shown in FIG. 8, when the recess 21 is formed in the CAP substrate 20, the magnitude of the stress applied to the device substrate 10 is, in descending order, as follows: the case where the bonding portion 30 is omitted, the case where the main component of the material of the bonding portion 30 is Au, the case where the main component of the material of the bonding portion 30 is a resin, and the case where the main component of the material of the bonding portion 30 is SiO₂. On the other hand, in the example shown in FIG. 8, when the recess 21 is not formed in the CAP substrate 20, the magnitude of the stress applied to the device substrate 10 is, in descending order, as follows: the case where the main component of the material of the bonding portion 30 is Au, the case where the bonding portion 30 is omitted, the case where the main component of the material of the bonding portion 30 is a resin, the case where the main component of the material of the bonding portion 30 is SiO₂. In other words, in the crystal unit 1 according to the present embodiment, when the recess 21 is formed in the CAP substrate 20, it is preferable that the main component of the material of the bonding portion 30 is Sion, it is more preferable that the main component of the material of the bonding portion 30 is a resin, it is more preferable that the main component of the material of the bonding portion 30 is Au, and it is more preferable to omit the bonding portion 30 and directly bond the CAP substrate 20 and the device substrate 10. On the other hand, in the crystal unit 1 according to the present embodiment, when the recess 21 is not formed in the CAP substrate 20, it is preferable that the main component of the material of the bonding portion 30 is SiO₂, it is more preferable that the main component of the material of the bonding portion 30 is a resin, it is more preferable to omit the bonding portion 30 and directly bond the CAP substrate 20 and the device substrate 10, and it is more preferable that the main component of the material of the bonding portion 30 is Au. Similarly, in the example shown in FIG. 8, when the recess 21 is formed in the CAP substrate 20, the magnitude of the stress applied to the device substrate 10 is, in descending order, as follows: the case where the bonding layer 50 is omitted, the case where the main component of the material of the bonding layer 50 is Au, the case where the main component of the material of the bonding layer 50 is a resin, the case where the main component of the material of the bonding layer 50 is SiO₂. On the other hand, in the example shown in FIG. 8, when the recess 21 is not formed in the CAP substrate 20, the magnitude of the stress applied to the device substrate 10 is, in descending order, as follows: the case where the main component of the material of the bonding layer 50 is Au, the case where the bonding layer 50 is omitted, the case where the main component of the material of the bonding layer 50 is a resin, the case where the main component of the material of the bonding layer 50 is SiO₂. In other words, in the crystal unit 1 according to the present embodiment, when the recess 21 is formed in the CAP substrate 20, it is preferable that the main component of the material of the bonding layer 50 is SiO₂, it is more preferable that the main component of the material of the bonding layer 50 is a resin, it is more preferable that the main component of the material of the bonding layer 50 is Au, and it is more preferable to omit the bonding layer 50 and directly bond the handle substrate 40 and the device substrate 10. On the other hand, in the crystal unit 1 according to the present embodiment, when the recess 21 is not formed in the CAP substrate 20, it is preferable that the main component of the material of the bonding layer 50 is SiO₂, it is more preferable that the main component of the material of the bonding layer 50 is a resin, it is more preferable to omit the bonding layer 50 and directly bond the handle substrate 40 and the device substrate 10, and it is more preferable that the main component of the material of the bonding layer 50 is Au.

The crystal unit 1 according to the present embodiment includes a device substrate 10, a CAP substrate 20 and a handle substrate 40, in which the device substrate 10 includes a crystal strip 11, a first excitation electrode 14a provided on a first principal surface 12a of the crystal strip 11 and a second excitation electrode 14b provided on a second principal surface 12b of the crystal strip 11, the CAP substrate 20 has an external terminal and is bonded to the first principal surface 12a of the crystal strip 11, and the handle substrate 40 is bonded to the second principal surface 12b of the crystal strip 11. The device substrate 10 has a principal surface defined by a first basic axis and a second basic axis intersecting the first basic axis. When an axis obtained by inclining, among the mutually intersecting first axis, second axis, and third axis, which are the crystallographic axes of crystal, the third axis around the first axis by a first predetermined angle is regarded as a first inclined axis, the device substrate 10 causes the first axis to correspond to the first basic axis and causes the first inclined axis to correspond to the second basic axis, wherein first predetermined angle is any angle included in an angle range of −90 to −60 degrees and the angle range of 80 to 90 degrees. Thus, when the crystal unit 1 is mounted on a mounting board 130, the stress applied to the device substrate 10 from the mounting board 130 can be reduced.

The above embodiment may be modified to other embodiments as follows.

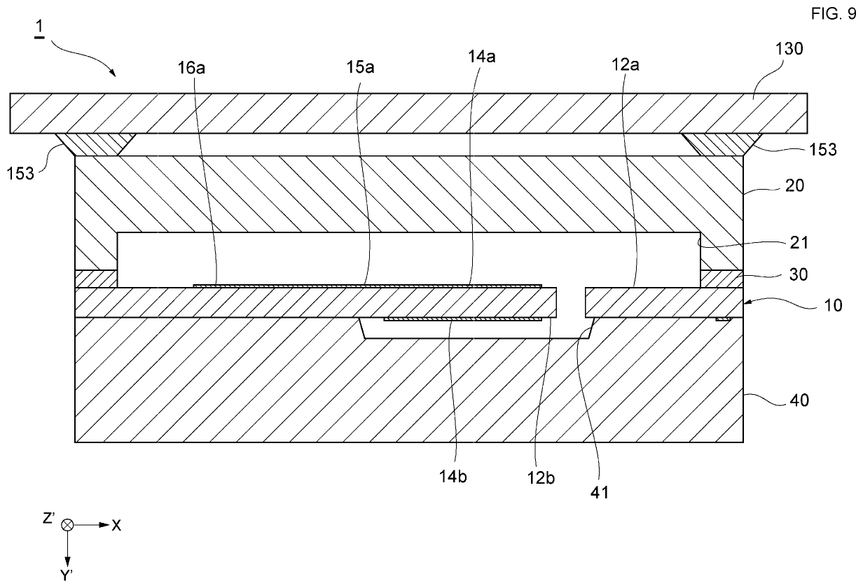

In the above embodiment, as shown in FIG. 9, the crystal unit 1 may have a configuration in which the device substrate 10 and the handle substrate 40 are directly bonded without the bonding layer 50, and the handle substrate 40 has a recess 41 that defines a space for the crystal strip 11 to vibrate.

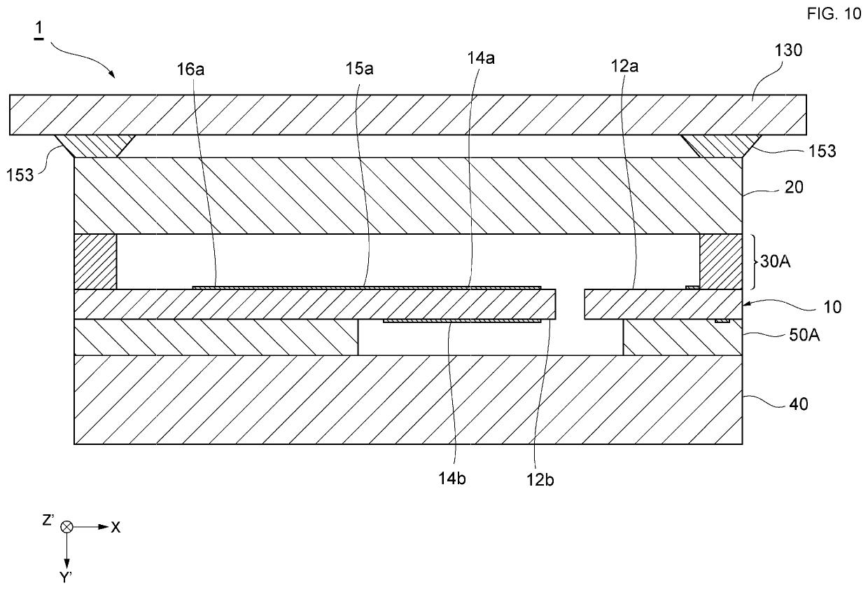

In the above embodiment, as shown in FIG. 10, the crystal unit 1 may have a configuration in which the first principal surface 12a of the crystal strip 11 and the CAP substrate 20 are bonded via a first bonding portion 30A, the second principal surface 12b of the crystal strip 11 and the handle substrate 40 are bonded via a second bonding portion 50A, and the first bonding portion 30A and the second bonding portion 50A constitute a space for the crystal strip 11 to vibrate.

Hereinafter, supplementary notes for some or all of the embodiments of the present invention will be given, and effects thereof will be described. The present invention is not limited to the following supplementary notes.

According to an aspect of the present invention, there is provided a piezoelectric oscillator that includes: a piezoelectric vibrating element that includes a piezoelectric strip, a first excitation electrode on a first surface of the piezoelectric strip, and a second excitation electrode on a second surface of the piezoelectric strip; a first crystal substrate having an external terminal and bonded to the first surface of the piezoelectric strip; and a second crystal substrate bonded to the second surface of the piezoelectric strip, wherein the first crystal substrate has a principal surface defined by a first basic axis and a second basic axis that intersects the first basic axis, and when an axis obtained by inclining, among mutually intersecting first axis, second axis, and third axis, which are crystallographic axes of crystal, the third axis around the first axis by a first predetermined angle is regarded as a first inclined axis, the first axis corresponds to the first basic axis and the first inclined axis corresponds to the second basic axis, and the first predetermined angle is any angle included in an angle range of −90 to −60 degrees and 80 to 90 degrees.

According to an aspect of the present invention, the piezoelectric oscillator is provided in which the second crystal substrate has a principal surface defined by a third basic axis and a fourth basic axis that intersects the third basic axis, and when an axis obtained by inclining, among the mutually intersecting first axis, second axis, and third axis, the third axis around the first axis by a second predetermined angle is regarded as a second inclined axis, the first axis corresponds to the third basic axis and the second inclined axis corresponds to the fourth basic axis, and the second predetermined angle is any angle included in an angle range of −90 to −30 degrees and 30 to 90 degrees.

According to an aspect of the present invention, the piezoelectric oscillator is provided in which the first crystal substrate has a recess on a surface facing the first surface of the piezoelectric strip.

According to an aspect of the present invention, the piezoelectric oscillator is provided in which the first surface of the piezoelectric strip is directly bonded to the first crystal substrate.

According to an aspect of the present invention, the piezoelectric oscillator is provided in which the first surface of the piezoelectric strip and the first crystal substrate are bonded via a first bonding material, and the first bonding material contains Au as a main component.

According to an aspect of the present invention, the piezoelectric oscillator is provided in which the first surface of the piezoelectric strip and the first crystal substrate are bonded via a first bonding material, and the first bonding material contains SiO₂ as a main component.

According to an aspect of the present invention, the piezoelectric oscillator is provided in which the first surface of the piezoelectric strip and the first crystal substrate are bonded via a first bonding material, and the first bonding material contains a resin as a main component.

According to an aspect of the present invention, the piezoelectric oscillator is provided in which the second surface of the piezoelectric strip and the second crystal substrate are directly bonded to each other.

According to an aspect of the present invention, the piezoelectric oscillator is provided in which the second surface of the piezoelectric strip and the second crystal substrate are bonded via a second bonding material, and the second bonding material contains Au as a main component.

According to an aspect of the present invention, the piezoelectric oscillator is provided in which the second surface of the piezoelectric strip and the second crystal substrate are bonded via a second bonding material, and the second bonding material contains SiO: as a main component.

According to an aspect of the present invention, the piezoelectric oscillator is provided in which the second surface of the piezoelectric strip and the second crystal substrate are bonded via a second bonding material, and the second bonding material contains a resin as a main component.

According to an aspect of the present invention, the piezoelectric oscillator is provided in which the second surface of the piezoelectric strip and the second crystal substrate are bonded via a second bonding material, and the second bonding material has a recess that defines a space for the piezoelectric strip to vibrate.

According to an aspect of the present invention, the piezoelectric oscillator is provided in which the second crystal substrate has a recess that defines a space for the piezoelectric strip to vibrate.

According to an aspect of the present invention, the piezoelectric oscillator is provided in which the first surface of the piezoelectric strip and the first crystal substrate are bonded via a first bonding material, the second surface of the piezoelectric strip and the second crystal substrate are bonded via a second bonding material, and the first bonding material and the second bonding material each include a recess that defines a space for the piezoelectric strip to vibrate.

According to an aspect of the present invention, the piezoelectric oscillator is provided in which the piezoelectric strip is an AT-cut type crystal substrate.

As described above, according to an aspect of the present invention, the stress transmitted to the piezoelectric vibrating element can be reduced.

It should be noted that the embodiments described above are intended to facilitate understanding of the present invention and should not be construed as limiting the present invention. The present invention may be modified or improved without departing from its spirit, and should include its equivalents. In other words, appropriate design changes made to the embodiment by those skilled in the art are included within the scope of the invention as long as they include the features of the present invention. For example, the elements included in the embodiments and the arrangements, materials, conditions, shapes, and sizes of the elements are not limited to those exemplified and may be modified as appropriate. Furthermore, the elements included in the embodiments may be combined with each other as long as it is technically possible, and the combinations thereof are within the scope of the present invention as long as they include the features of the present invention.

### REFERENCE SIGNS LIST

1 crystal unit
10 device substrate
11 crystal strip
11A vibrating portion
11B groove
11C holding portion
12a first principal surface
12b second principal surface
14a first excitation electrode
14b second excitation electrode
15a, 15b extended electrode
16a, 16b connecting electrode
17 via electrode
20 CAP substrate
30 bonding portion
30A first bonding portion
40 handle substrate
41 recess
50 bonding layer
50A second bonding portion
51 recess
100 crystal oscillator
130 mounting board
140 lid member
153 solder
156 electronic component
166 bonding wire

1. A piezoelectric oscillator comprising:
a piezoelectric vibrating element that includes a piezoelectric strip, a first excitation electrode on a first surface of the piezoelectric strip, and a second excitation electrode on a second surface of the piezoelectric strip;
a first crystal substrate having an external terminal and bonded to the first surface of the piezoelectric strip; and
a second crystal substrate bonded to the second surface of the piezoelectric strip,
wherein
the first crystal substrate has a principal surface defined by a first basic axis and a second basic axis that intersects the first basic axis, and when an axis obtained by inclining, among mutually intersecting first axis, second axis, and third axis, which are crystallographic axes of crystal, the third axis around the first axis by a first predetermined angle is regarded as a first inclined axis, the first axis corresponds to the first basic axis and the first inclined axis corresponds to the second basic axis, and
the first predetermined angle is any angle included in an angle range of −90 to −60 degrees and 80 to 90 degrees.

2. The piezoelectric oscillator according to claim 1, wherein
the second crystal substrate has a principal surface defined by a third basic axis and a fourth basic axis that intersects the third basic axis, and when an axis obtained by inclining, among the mutually intersecting first axis, second axis, and third axis, the third axis around the first axis by a second predetermined angle is regarded as a second inclined axis, the first axis corresponds to the third basic axis and the second inclined axis corresponds to the fourth basic axis, and
the second predetermined angle is any angle included in an angle range of −90 to −30 degrees and 30 to 90 degrees.

3. The piezoelectric oscillator according to claim 1, wherein the first crystal substrate has a recess on a surface facing the first surface of the piezoelectric strip.

4. The piezoelectric oscillator according to claim 1, wherein the first surface of the piezoelectric strip is directly bonded to the first crystal substrate.

5. The piezoelectric oscillator according to claim 3, wherein
the first surface of the piezoelectric strip and the first crystal substrate are bonded via a first bonding material, and
the first bonding material contains Au as a main component.

6. The piezoelectric oscillator according to claim 1, wherein
the first surface of the piezoelectric strip and the first crystal substrate are bonded via a first bonding material, and
the first bonding material contains SiO₂ as a main component.

7. The piezoelectric oscillator according to claim 1, wherein
the first surface of the piezoelectric strip and the first crystal substrate are bonded via a first bonding material, and
the first bonding material contains a resin as a main component.

8. The piezoelectric oscillator of claim 1, wherein the second surface of the piezoelectric strip and the second crystal substrate are directly bonded to each other.

9. The piezoelectric oscillator according to claim 1, wherein
the second surface of the piezoelectric strip and the second crystal substrate are bonded via a second bonding material, and
the second bonding material contains Au as a main component.

10. The piezoelectric oscillator according to claim 1, wherein
the second surface of the piezoelectric strip and the second crystal substrate are bonded via a second bonding material, and
the second bonding material contains SiO₂ as a main component.

11. The piezoelectric oscillator according to claim 1, wherein
the second surface of the piezoelectric strip and the second crystal substrate are bonded via a second bonding material, and
the second bonding material contains a resin as a main component.

12. The piezoelectric oscillator according to claim 1, wherein
the second surface of the piezoelectric strip and the second crystal substrate are bonded via a second bonding material, and
the second bonding material has a recess that defines a space for the piezoelectric strip to vibrate.

13. The piezoelectric oscillator according to claim 1, wherein the second crystal substrate has a recess that defines a space for the piezoelectric strip to vibrate.

14. The piezoelectric oscillator according to claim 1, wherein
the first surface of the piezoelectric strip and the first crystal substrate are bonded via a first bonding material,
the second surface of the piezoelectric strip and the second crystal substrate are bonded via a second bonding material, and
the first bonding material and the second bonding material each include a recess that defines a space for the piezoelectric strip to vibrate.

15. The piezoelectric oscillator according to claim 1, wherein
the first surface of the piezoelectric strip and the first crystal substrate are bonded via a first bonding material, and
the second surface of the piezoelectric strip and the second crystal substrate are bonded via a second bonding material.

16. The piezoelectric oscillator according to claim 15, wherein the first bonding material contains at least one of Au as a main component, SiO₂ as a main component, and a resin as a main component.

17. The piezoelectric oscillator according to claim 16, wherein the second bonding material contains at least one of Au as a main component, SiO₂ as a main component, and a resin as a main component.

18. The piezoelectric oscillator according to claim 15, wherein the second bonding material contains at least one of Au as a main component, SiO₂ as a main component, and a resin as a main component.

19. The piezoelectric oscillator according to claim 1, wherein the piezoelectric strip is an AT-cut crystal substrate.
